(19) United States
(12) Patent Application Publication
(10) Pub. No.: US 2023/0078547 A1
(43) Pub. Date: Mar. 16, 2023

(54) SMART POLE POWER SYSTEM

(71) Applicant: PEGATRON CORPORATION, TAIPEI CITY (TW)

(72) Inventors: Chih-Shen Lo, Taipei City (TW); Hao-Hsiu Tsai, Taipei City (TW)

(73) Assignee: PEGATRON CORPORATION, TAIPEI CITY (TW)

(21) Appl. No.: 17/890,180

(22) Filed: Aug. 17, 2022

(30) Foreign Application Priority Data
Sep. 16, 2021 (TW) 110134684

(51) Int. Cl. H02J 7/00

(52) U.S. Cl. CPC H02J 7/0025; H02J 7/0042; H02J 7/0047

(57) ABSTRACT

A smart pole power system including a distribution board, multiple alternating current (AC) power devices, a power splitter, and at least one wired network device is provided. The distribution board is coupled to an AC power source to provide multiple AC voltages. The AC power devices are coupled to the distribution board and receive the AC voltages. The AC power devices include a network switch. The network switch receives one of the AC voltages to provide at least one network power supply signal. The power splitter is coupled to the network switch. The power splitter receives one of the network power supply signals and separates a supply voltage signal from the received network power supply signal. The at least one wired network device includes a non-network power supply device. The non-network power supply device is powered by the supply voltage upon reception of the supply voltage.

### CROSS-REFERENCE TO RELATED APPLICATION

This application claims the priority benefit of Taiwan application serial no. 110134684, filed on Sep. 16, 2021. The entirety of the above-mentioned patent application is hereby incorporated by reference herein and made a part of this specification.

### BACKGROUND

### Technology Field

The disclosure relates to an electric pole power system, and in particular, to a smart pole power system.

### Description of Related Art

For the conventional street lights or poles, the demand for lots of attached equipment has increased due to the progress of the times, such as network cameras, Internet phones, WiFi access points (APs) and other equipment. The equipment needs to use specific alternating current to direct current (AC-to-DC) power supplies. If the power supply is hung outside the pole, it will make the appearance messy and affect the aesthetics of street lights or poles. In addition, the better waterproofing may be necessary for the power supply.

### SUMMARY

The disclosure provides a smart pole power system, which may greatly reduce the number of power supply components, so as to greatly reduce the installation space and the wiring layout space taken up by those components, and further improve the aesthetics of appearance of street lamps or poles.

The smart pole power system of the disclosure includes a distribution board, multiple alternating current (AC) power devices, a power splitter, and at least one wired network device. The distribution board is coupled to an AC power source to provide multiple AC voltages. The AC power devices are coupled to the distribution board and receive the AC voltages, and the AC power devices include a network switch. The network switch receives one of the AC voltages to provide at least one network power supply signal. The power splitter is coupled to the network switch. The power splitter receives one of the network power supply signals and separates a supply voltage signal from the received network power supply signal. The at least one wired network device includes a non-network power supply device. The non-network power supply device is coupled to the power splitter and powered by the supply voltage upon reception of the supply voltage.

Based on the above, the smart pole power system of the embodiment of the disclosure supplies power to the wired network device through the network switch, so as to greatly reduce the number of power supply components as well as greatly reduce the installation space and the wiring layout space taken up by those components.

In order to make the aforementioned features and advantages of the disclosure comprehensible, embodiments accompanied with drawings are described in detail as follows.

### BRIEF DESCRIPTION OF THE DRAWINGS

FIG. 1 is a system schematic diagram of a smart pole power system according to an embodiment of the disclosure.

FIG. 2 is a system schematic diagram of a smart pole power system according to another embodiment of the disclosure.

### DESCRIPTION OF THE EMBODIMENTS

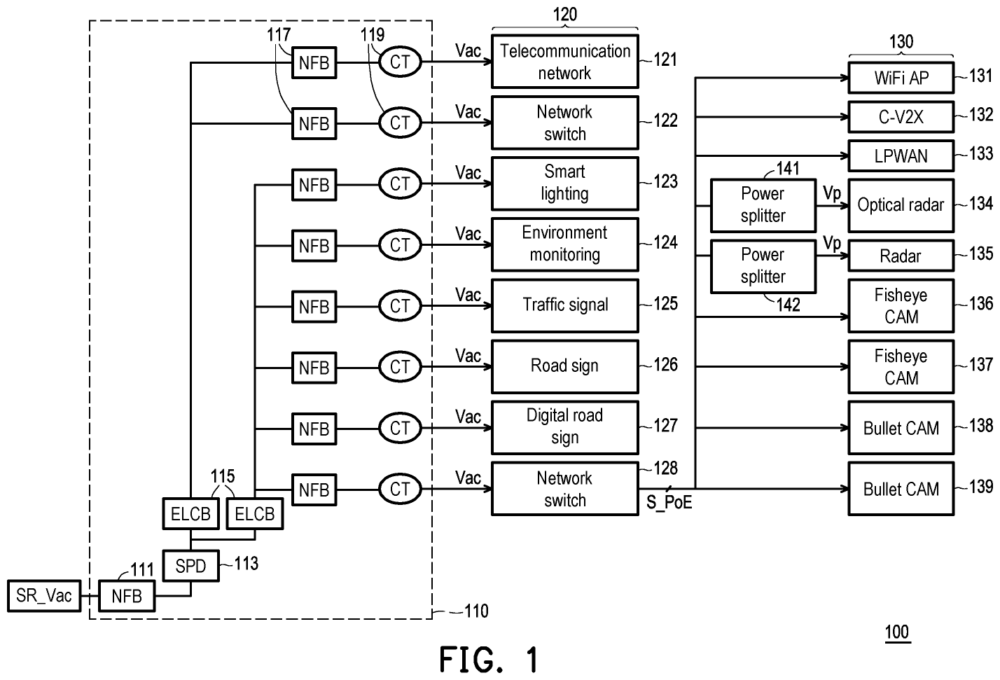

FIG. 1 is a system schematic diagram of a smart pole power system according to an embodiment of the disclosure. Referring to FIG. 1, in the embodiment, a smart pole power system 100 includes a distribution board 110, multiple alternating current (AC) devices 120 (e.g., a telecommunication network base station 121, network switches 122 and 128, a smart lighting module 123, an environment monitoring module 124, a traffic signal module 125, a road sign module 126, and a digital road sign module 127), and at least one wired network device 130 (e.g., at least one of a Wi-Fi access point (AP) 131, a cellular vehicle-to-everything (C-V2X) roadside equipment 132, a low power wide area network (LPWAN) communication module 133, an optical radar 134, a radar 135, and at least one network camera (CAM)). The network cameras include, for example, fisheye cameras 136 and 137 and bullet cameras 138 and 139.

The distribution board 110 is coupled to an AC power source SR_Vac to provide multiple AC voltages Vac. The AC power source SR_Vac may be referred to as a power cable of a power company, a transformer, or electromechanical equipment with similar functions. However, the embodiment of the disclosure is not limited thereto. The AC devices 120 are coupled to the distribution board 110 and receive the AC voltages Vac for operation. The network switch 128 receives one of the AC voltages Vac to provide at least one network power supply signal S_PoE to the wired network device 130 via at least one network transmission line.

The wired network device 130 is coupled to the network switch 128 and powered by the corresponding network power supply signal S_PoE. Further, if the wired network device 130 is a network power supply device (e.g. the Wi-Fi AP 131, the C-V2X roadside equipment, the LPWAN communication module, the fisheye cameras 136 and 137, or the bullet cameras 138 and 139), the network power supply device receives the network power supply signal S_PoE and is directly powered by the network power supply signal S_PoE. If the wired network device 130 is a non-network power supply device (e.g., the optical radar 134 or the radar 135), the non-network power supply device receives the corresponding network power supply signal S_PoE through a power splitter 141 to use the network power supply signal S_PoE as the power supply. The above is an example for illustration, and whether the wired network device 130 is capable of receiving the network power supply signal S_PoE directly depends on the circuit design, and the embodiment of the disclosure is not limited thereto.

According to the above, the smart pole power system 100 is always capable of powering the wired network device 130 through the network switches 122 or 128. Even if the wired network device 130 itself cannot directly use the network power supply signal S_PoE, the network switches 122 or 128 may use the power splitters 141 or 142 to output a suitable direct current (DC) voltage Vp through the network transmission line to supply the back-end wired network device 130. In this way, the smart pole power system 100 may lower the number of power adapters used by the wired network device 130, so as to greatly reduce the number of power supply components as well as greatly reduce the installation space and the wiring layout space taken up by those components.

In the embodiment of the disclosure, the distribution board 110 includes a main no-fuse breaker (NFB) 111, a surge protection device (SPD) 113, multiple earth leakage circuit breakers (ELCBs) 115, multiple shunt NFBs 117, and multiple current transfers (CTs) 119.

The main NFB 111 is coupled to the AC power source SR_Vac, and the SPD 113 is coupled in series with the main NFB 111. The ELCBs 115 are coupled to the SPD 113, and each of the shunt NFBs 117 is coupled to one of the ELCBs 115. The CTs 119 are coupled to the shunt NFBs 117.

In the embodiment of the disclosure, the wired network may be an Ethernet network, and the network power supply signal S_PoE may be an Ethernet network power supply signal. However, the embodiment of the disclosure is not limited thereto.

In the embodiment of the disclosure, the power splitters 141 or 142 may select a specific voltage output model according to the requirements of the back-end wired network device 130 to meet the DC power supply voltage requirements for all the wired network devices 130. Further, the power splitters 141 or 142 are coupled to the network switch 128, and separate the supply voltage signal Vp from the received network power supply signal S_PoE. The voltage provided by each of the supply voltage signals Vp is consistent with the source voltage of the corresponding non-network power supply device.

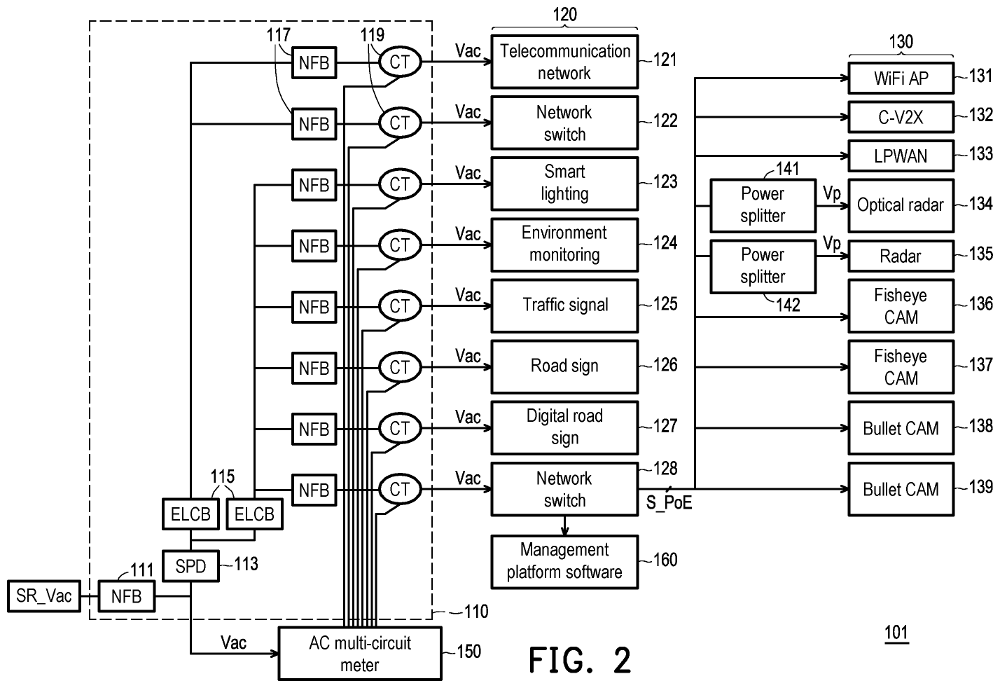

FIG. 2 is a system schematic diagram of a smart pole power system according to another embodiment of the disclosure. Referring to FIGS. 1 and 2, a smart pole power system 101 is substantially the same as the smart pole power system 100, except that the smart pole power system 101 further includes an AC multi-circuit meter 150 and management platform software 160. The AC multi-circuit meter 150 may be coupled to the main NFB 111 to receive the AC voltage Vac, and is powered by the received AC voltage Vac.

In the embodiment, the network switches (e.g., 122 or 128) have power consumption monitoring capabilities, that is, the network switches (e.g., 122 or 128) may monitor the power consumption of the network power signals S_PoE outputted by each network port, and may report the power consumption of all the network power supply signals S_PoE through the network transmission line. The network switches (e.g., 122 or 128) may report periodically, which may be determined according to the capabilities of the network switches (e.g., 122 or 128) and system requirements, but the embodiment of the disclosure is not limited thereto.

The management platform software 160 is coupled to the network switch 128 to receive the power consumption of all the network power supply signals S_PoE (i.e., the power consumption of all the wired network devices 130) reported by the network switches (e.g., 122 or 128), and estimate the total DC power consumption of all the network power supply signals S_PoE in a billing cycle (that is, the total DC power consumption of all the wired network devices 130). The billing cycle may be thirty days.

In addition, the management platform software 160 may calculate the power consumption distribution (or the power consumption ratio) of at least one of the network power supply signals S_PoE provided by the network switch 128, so as to calculate the electricity bill for each of the wired network devices 130 coupled to the network switch 128. In other words, the electricity bill of the network switch 128 may be divided into the electricity bill of each of the wired network devices 130 by the power consumption distribution (or the power consumption ratio).

In the embodiment, the management platform software 160 may obtain the real-time power consumption of each of the wired network devices 130 through the network switch 128, calculate the power consumption degree cumulatively, and then distribute the electricity bill of the network switch 128 proportionally according to the power consumption (kWh). In this way, the power consumption of each of the wired network devices 130 and the corresponding electricity bill may be clearly calculated.

The CTs 119 are configured to monitor the power consumption of the AC voltages Vac (that is, to monitor the power consumption of the AC devices 120), and the AC multi-circuit meter 150 is coupled to all the CTs 119 to estimate the total AC power consumption of all the AC voltages Vac in the billing cycle (that is, to count the total AC power consumption of all the AC power devices 120).

In summary, the smart pole power system of the embodiment of the disclosure supplies power to the wired network devices through the network switch, so as to greatly reduce the number of power supply components as well as greatly reduce the installation space and the wiring layout space taken up by those components. In addition, if the network switch has the power consumption monitoring capability, the management platform software may receive the power consumption of each of the wired network devices 130 reported by the network switch, and estimate the total DC power consumption of all the wired network devices 130, so as to calculate the power consumption distribution (or the power consumption ratio) of each of the wired network devices connected to the network switch.

Although the disclosure has been described with reference to the above embodiments, the described embodiments are not intended to limit the disclosure. People of ordinary skill in the art may make some changes and modifications without departing from the spirit and the scope of the disclosure. Thus, the scope of the disclosure shall be subject to those defined by the attached claims.

What is claimed is:

1. A smart pole power system, comprising:
a distribution board, coupled to an alternating current (AC) power source to provide a plurality of AC voltages;
a plurality of AC devices, coupled to the distribution board and receiving the AC voltages, the AC devices comprising a network switch, and the network switch receiving one of the AC voltages to provide at least one network power supply signal;
a power splitter, coupled to the network switch, the power splitter receiving one of the at least one network power supply signal and separating a supply voltage signal from the received network power supply signal; and
at least one wired network device comprising a non-network power supply device, the non-network power supply device being coupled to the power splitter and powered by the supply voltage signal upon reception of the supply voltage signal.

2. The smart pole power system according to claim 1, wherein the at least one wired network device further comprises a network power supply device, the network power supply device receives another one of the at least one network power supply signal and is powered by the received network power supply signal.

3. The smart pole power system according to claim 1, wherein the at least one wired network device comprises at least one of a Wi-Fi access point, an optical radar, a radar, a network camera, a vehicle-to-everything roadside equipment, and a low power wide area network communication module.

4. The smart pole power system according to claim 1, wherein the AC devices further comprise at least one of a telecommunication network base station, a smart lighting module, a traffic signal module, an environment monitoring module, a road sign module, and a digital road sign module.

5. The smart pole power system according to claim 1, wherein the at least one network power supply signal is an Ethernet network power supply signal.

6. The smart pole power system according to claim 1, wherein the network switch monitors power consumption of each of the at least one network power supply signal, the smart pole power system further comprises management platform software, and the management platform software is coupled to the network switch to estimate total direct current (DC) power consumption of all the at least one network power signal in a billing cycle.

7. The smart pole power system according to claim 6, wherein the distribution board comprises a plurality of current transfers for monitoring power consumption of each of the AC voltages, the smart pole power system further comprises an AC multi-circuit power meter, and the AC multi-circuit power meter is coupled to the current transfers to estimate the total AC power consumption of all the AC voltages in the billing cycle.

8. The smart pole power system according to claim 7, wherein the billing cycle is thirty days.
